(19) United States
(12) Patent Application Publication
(10) Pub. No.: US 2023/0401360 A1
(43) Pub. Date: Dec. 14, 2023

(54) SYSTEM DESIGN BASED ON PROCESS FLOW DIAGRAM INFORMATION EXTRACTION AND GENERATIVE MODELS

(71) Applicant: Novity, Inc., San Carlos, CA (US)

(72) Inventors: Ion Matei, Mountain View, CA (US); Leora Morgenstern, Silver Spring, MD (US); Kai Frank Goebel, Mountain View, CA (US); Johan de Kleer, Los Altos, CA (US)

(73) Assignee: Novity, Inc., San Carlos, CA (US)

(21) Appl. No.: 17/835,778

(22) Filed: Jun. 8, 2022

(51) Int. Cl. G06F 30/27; G06F 30/18; G06N 3/12; G06V 30/422

(52) U.S. Cl. CPC G06F 30/27; G06F 30/18; G06N 3/126; G06V 30/422

(57) ABSTRACT

One embodiment provides a method and a system for automated design of a physical system. During operation, the design system obtains qualitative and quantitative design requirements associated with the physical system and inputs the qualitative design requirements to a trained machine-learning model to generate a topology of the physical system. The topology specifies a number of components and connections among the components. The design system then determines parameters of the components based on the quantitative design requirements.

### BACKGROUND

### Field

This disclosure is generally related to design of physical systems, such as a heating, ventilation, and air conditioning (HVAC) system. More specifically, this disclosure is related to training a machine-learning model to output designs of physical systems.

### Related Art

Design of physical systems is the next frontier in artificial intelligence (AI). A typical process for designing a physical system starts with the designer proposing a system architecture or topology based on experience and domain expertise. The architecture/topology can include a set of physical components and their interconnections. Subsequently, based on a set of design requirements, the designer can instantiate the components with parameter values as part of a parameter sweep process, until the given requirements are met. Although there are well-established automated processes for parameter selection, automated generation of an initial system topology can be challenging.

### SUMMARY

One embodiment provides a method and a system for automated design of a physical system. During operation, the automated design system obtains qualitative and quantitative design requirements associated with the physical system and inputs the qualitative design requirements to a trained machine-learning model to generate a topology of the physical system. The topology specifies a number of components and connections among the components. The design system then determines parameters of the components based on the quantitative design requirements.

In a variation on this embodiment, the machine-learning model is a generative model.

In a further variation, the design system trains the generative model. Training the generative model comprises: obtaining images of a plurality of process flow diagrams (PFDs) associated with known systems, extracting, from the images, topology information associated with the known systems, and converting the topology information into a predetermined format.

In a further variation, extracting the topology information comprises applying an image-processing technique to detect components and connections among the detected components within each image.

In a further variation, training the generative model further comprises associating a label with the converted topology information from each PFD, wherein the label comprises a functional description of a system corresponding to the PFD.

In a further variation, the predetermined format comprises a formal language representation of the topology information.

In a further variation, the formal language representation comprises a number of component-connection sequences, and a respective component-connection sequence comprises a statement indicating a connection order of a number of components.

In a further variation, the generative model comprises a natural language processing (NLP) machine-learning model comprising one or more of: an N-gram language model, a recurrent neural net (RNN) language model, a hidden Markov model, a model implementing probabilistic context-free grammars, a naïve Bayes model, a latent Dirichlet allocation (LDA) model, a sequence to sequence (Seq2Seq) model, and a transformer model.

In a variation on this embodiment, determining the parameters of the components comprises using an optimization technique to search a parameter space associated with a respective component.

In a further variation, in response to failing to find parameters of the components meeting the quantitative design requirements, the trained machine-learning model generates an additional topology of the physical system.

### BRIEF DESCRIPTION OF THE FIGURES

FIG. 1 illustrates an exemplary process flow diagram (PFD) of an amine-treating plant.

FIG. 2 presents a flowchart illustrating an exemplary process for training a machine-learning model for generating topologies of to-be-designed physical systems, according to one embodiment.

FIG. 3 presents a block diagram of an exemplary machine-learning-training system for training a machine-learning model for generating topologies of to-be-designed physical systems, according to one embodiment.

FIG. 4 presents a flowchart illustrating an exemplary process for generating a design solution of a physical system, according to one embodiment.

FIG. 5 illustrates a block diagram of an exemplary automated system-design apparatus for designing physical systems, according to one embodiment.

FIG. 6 illustrates an exemplary computer system that facilitates automated design of physical systems, according to one embodiment.

In the figures, like reference numerals refer to the same figure elements.

### DETAILED DESCRIPTION

The following description is presented to enable any person skilled in the art to make and use the embodiments and is provided in the context of a particular application and its requirements. Various modifications to the disclosed embodiments will be readily apparent to those skilled in the art, and the general principles defined herein may be applied to other embodiments and applications without departing from the spirit and scope of the present disclosure.

Thus, the present invention is not limited to the embodiments shown but is to be accorded the widest scope consistent with the principles and features disclosed herein.

### Overview

Embodiments described herein provide a system and method for automated design of a physical system (e.g., a heating system or an HVAC system). To facilitate automated system design, a machine-learning model (e.g., a generative model) can be trained to output an initial topology of a to-be-designed physical system. Training the machine-learning model can involve collecting a large amount of training samples. Moreover, collecting the training samples can include extracting meaningful information from process flow diagrams (PFDs) of many different systems and processing the extracted information into a predetermined format (e.g., a text-based format). In one embodiment, information extracted from the PFD of a system can include names (or other types of representations) of the components and their connections, referred to as component-connection sequences. In addition, ontological constraints can also be used as negative examples A generative model can then be trained using component-connection sequences extracted from many PFDs as positive training samples and optionally using the ontological constraints as negative training samples. The trained generative model can then generate an initial topology (referred to as a meta design) for a to-be-designed system according to qualitative requirements of the to-be-designed system. The meta design can be instantiated using explicit components from a component library. Parameter optimization can also be performed to find parameters of the components that can satisfy the qualitative requirements of the to-be-designed system. In some embodiments, the automated design system can generate a number of different design solutions for a physical system that meet the set of design requirements, including both the qualitative and quantitative requirements. The generated design solutions can further be evaluated using other metrics, such as manufacturing cost and maintenance cost, to determine a preferred design solution.

### Automated System Design Using Generative Models

The design of a physical system can start with a system architecture that includes a number of interconnected components. For example, the design of a heating system can start with an architecture that includes a pump, a heating source (i.e., a burner), a valve, a radiator, and a set of pipes through which a fluid is circulated. The pump moves the fluid, the burner heats the fluid, and the valve controls the flow rate of the fluid and hence controls how much heat is exchanged. Each of these physical components has parameters that can determine the overall system behavior. For instance, if the system requirement is to have a minimum temperature at the radiator, appropriate physical parameters of the components (e.g., the power of the pump and the burner, the diameter of the pipes, etc.) need to be chosen to achieve this requirement. A low-power burner together with an underpowered pump and pipes with small diameters may not achieve the required minimum temperature at the radiator.

To enable automated system design, there needs to be a mechanism that can automatically generate, based on the functional and behavior requirement of a to-be-designed system, an initial topology for the to-be-designed system. Because there are a wide variety of physical systems, and because designing the system topology requires expert knowledge, automated generation of the system topology is challenging. In some embodiments, an automated design system can include an AI-based topology-generation module that uses trained generative models to generate the initial topology for a to-be-designed physical system based on the functional and behavior requirement of the to-be-designed physical system.

A generative model is a machine-learning model that models the joint probability distribution P(X,Y) on given observable variable X and target variable Y. Because the model learns a probability distribution for the dataset, it can reference this probability distribution to generate new data instances. In the example of the system design, the observable variable X can be the system topology (or architecture) and the target variable Y can be a label associated with the system, such as the name or functional description of the system. In the example of the heating system, the topology or architecture of the heating system is the observable variable X, and the label “heating system” is the target variable Y. The dataset from which the generative model learns joint probability distribution P(X,Y) can be the topologies of many different types of systems (e.g., different heating systems, cooling systems, HVAC systems, electrical systems, mechanical systems, etc.) and their corresponding labels.

Training a generative model requires a relatively large dataset or training samples that include the topologies of many different types of systems. However, although there are a plethora of system schematics and diagrams representing topologies of various systems (e.g., circuit layouts, single-line diagrams (SLDs), process flow diagrams (PFDs)), most of them are in a format that is not directly amenable for training the generative model. To obtain the training samples, in some embodiments, meaningful information can be extracted from these diagrams, including the PFDs, and the extracted information can then be processed to generate training samples of a predetermined format.

In this disclosure, we use process flow diagrams as an example. A process flow diagram (PFD) is a type of flowchart that illustrates the relationships among major components at an industrial plant. PFDs have been widely used in chemical engineering and process engineering. In addition, a similar concept has been applied to other processes as well. Various industry standards govern the rules and symbols used for generating the PFDs. For example, a number of standardization organizations, such as the International Organization for Standardization (ISO) and American National Standards Institute (ANSI), have provided standards (e.g., ISO 15519 and ISO 10628) for generating PFDs. These standards have defined symbols that can be used to represent different types of equipment (e.g., valves, pumps, vessels, motors, etc.). PFDs may be generated using software (e.g., process simulators, CAD packages, flowchart software, etc.) or may be generated manually. PFDs of many commercial processes can be found in the literature (e.g., in encyclopedias of chemical technologies or in patent databases). In other words, there are a large number of potential training samples.

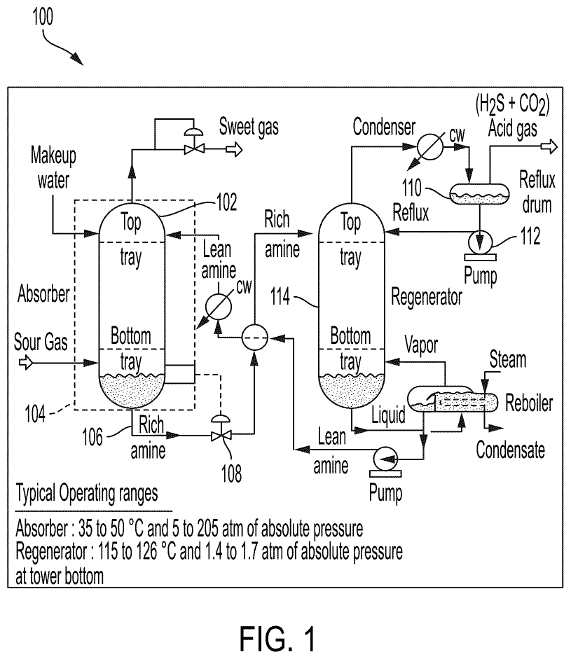

FIG. 1 illustrates an exemplary process flow diagram (PFD) of an amine-treating plant. As shown in FIG. 1, PFD 100 includes a number of components, such as reaction vessels, pipes, pumps, valves, etc. Although the symbols for the components are standard and their connections are straightforward, it can be difficult to use PFD 100 directly as a training sample that can be used to train a machine-learning model (e.g., a generative model). To overcome this problem, in some embodiments, meaningful information can be extracted from PFD 100 and processed to generate a training sample that can represent the system architecture in a format amenable for generative model training.

In some embodiments, image processing-based techniques, such as object detection, can be used to detect the components in a PFD. Object detection can detect the presence of an object in an image and draws a bounding box around that object. Using FIG. 1 as an example, an object-detection operation may detect a tray column 102 and draw a bounding box 104 around it. Note that the object-detection operation can include two processes. One process involves classifying an object's type (e.g., classifying object 102 as a tray column), and the other process involves drawing a box 104 around object 102. Various object-detection techniques or models can be used, including but not limited to: region-based convolutional neural network (R-CNN), fast R-CNN, faster R-CNN, mask R-CNN, single shot multibox detector (SSD), you only look once (YOLO), objects as points, data augmentation strategies for object detection, etc.

In some cases, the PFDs are labeled, meaning that the functions or names of the systems are provided, thus making it possible for the object-detection process to obtain domain-specific ontology of components in the PFDs and to use such information to identify the components and connections among them. In some cases, a PFD may not be labeled, and the domain expert can associate a label describing its functionality with the PFD. For example, PFD 100 shown in FIG. 1 is not labeled, and a domain expert can attach a label stating, “amine-treating plant.” Other examples of a label for a PFD can include but are not limited to: a heater, a cooler, an analog filter, a digital filter, etc.

Once the components and their connections are identified, the system architecture/topology can be converted into a predetermined format. In some embodiments, the system topology can be converted to a formal language representation (e.g., using first-order logic). For example, the system topology shown in the PFD can be converted to a number of statements. In further embodiments, the statements can be text-based. Using FIG. 1 as an example, one such statement can be “tray column 102 connected to pipe 106 connected to valve 108.” An additional statement can be “reflux drum 110 connected to pump 112 connected to tray column 114.” Note that in the later statement the connection pipe is omitted, as the pipes are default connections in this type of system. In addition to text, the statements can also include symbols. One exemplary statement can be “tray column 102 pipe 106 valve 108.” In one more example, the statements can be graphic-based and may use component symbols instead of component names. These statements describe the sequential connection relationship among components and, hence, can be referred to as component-connection sequences.

In alternative embodiments, the system topology can be converted to other formats, such as formal logic, graph neural networks, and languages inspired from chemical molecule representation (e.g., the simplified molecular-input line-entry system (SMILES) formalism). By collecting the PFDs, extracting topology information from the PFDs, converting the topology information to a predetermined format (referred to as a model-amenable format), and attaching labels to the PFDs, one can build a library of examples of system architectures. These examples can then be used to train a machine-learning model (e.g., a generative model) that can generate a system topology, given a set of quantitative requirements.

In some embodiments, in addition to the topology information expressed in a model-amenable format, a set of ontological constraints, which specify the ways in which components cannot be connected to one another can also be used in the model training. For heating systems, an exemplary constraint can be that a heat sensor that measures the temperature of a heat exchanger should not be attached to a pipe. Such constraints can be used to provide negative training samples that can be used to train the machine-learning model for system topology generation.

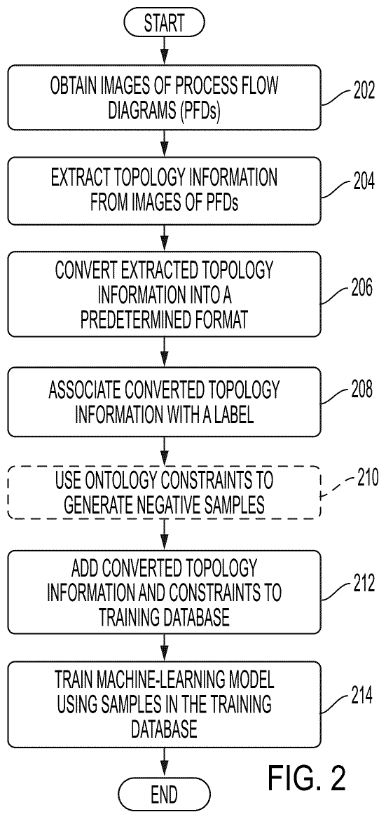

FIG. 2 presents a flowchart illustrating an exemplary process for training a machine-learning model for generating topologies of to-be-designed physical systems, according to one embodiment. During operation, images of a number of PFDs of existing physical systems or known working systems are obtained (operation 202). The existing or working systems are systems that are previously designed and proven to be working. In some embodiments, the PFDs may exist in literature (e.g., books, published papers, encyclopedias, etc.) in paper format, and obtaining the PFDs can include scanning or capturing images of the PFDs. In some embodiments, the PFDs may be generated by software, and images of the PFDs can be outputted by the software.

Subsequently, a machine-learning-based image-processing technique can be used to extract topology information from the images of the PFDs (operation 204). For example, various object-detection techniques (e.g., R-CNN, fast R-CNN, faster R-CNN, mask R-CNN, SSD, YOLO, objects as points, data augmentation strategies for object detection, etc.) can be used to identify components within a PFD and their connections. In some embodiments, when identifying the components and their connections, the machine-learning algorithm can use ontology of the system described in the PFD to facilitate the object-detection process. Note that, in addition to component symbols, the PFD of a system may also include textual information, as shown in FIG. 1. In one embodiment, the machine-learning algorithm can process the textual information (e.g., associating a textual label with a nearby component symbol) and use the processed textual information to assist the object detection. In an alternative embodiment, the machine-learning algorithm may ignore the textual information and only processes graphical elements within the PFD, including the component symbols and the lines connecting them.

The topology information extracted from the PFD (e.g., a list of components and connections among these components) can then be converted into a predetermined format (e.g., a formal language representation) (operation 206). In one embodiment, the topology information extracted from the PFD can be converted to a number of component-connection sequences. A simplest system topology comprising a number of sequentially connected components can be represented using a single component-connection sequence, whereas a more complex system with interconnected components may be represented using multiple component-connection sequences. In some embodiments, converting the topology information into the predetermined format can be performed in an automated fashion with the assistance of software. For example, each identified component can be represented using its name and each connection can be represented using the phrase “connected to” or an arrow. In general, the format can be flexible, as long as a general set of rules have been followed (e.g., using propositional logic, using first-order logic, using all text, using arrows to represent directional connections, using component symbols, using SMILES formulations, etc.).

A label can then be associated with or attached to the converted topology information (i.e., the component-connection sequences) (operation 208). The label can describe the functionality (e.g., amine treatment, heater, cooler, analog or digital filter, etc.) of the system. In certain scenarios, the PFD image may already include the label, and the image-processing algorithm can read and attach the label. In other scenarios, the PFD image does not include the label, and a domain expert can manually attach the label to the converted topology information.

In addition to information extracted from the PFDs, the domain expert may also use ontological constraints to generate negative training samples (optional operation 210). For example, the ontological constraints can also be converted into the predetermined format (e.g., a forbidden component connection sequence such as “heat sensor not connected to pipe”).

The converted topology information and the constraints can be added to a training database (operation 212). The training database can include the formal language representation of a large number of PFDs. In some embodiments, the training database can include a large number of labeled sets of component-connection sequences, with each labeled set of component-connection sequences corresponding to a system PFD. In addition, the training database can include a number of constraints (i.e., negative samples).

Samples in the training database can then be used to train a machine-learning model that can predict a next element in a sequence, given the function/label of the sequence (operation 214). Such models are typically generative models. In some embodiments, the labeled sets of component-connection sequences can be used to train various generative models used for natural language processing (NLP), including but not limited to: N-gram/recurrent neural net (RNN) language models, hidden Markov models, probabilistic context-free grammars, naïve Bayes, latent Dirichlet allocation, sequence to sequence (Seq2Seq) models, transformers, etc. Among these models, Seq2Seq type of models are advantageous. They can start with a component in an architecture, and the model will iteratively propose new components and connections, until a system architecture is built. Depending on the type of the to-be-trained model, different training methods can be used. For deep-learning (DL) models (e.g., RNNs and Seq2Seq), DL training platforms, such as Pytorch, TensorFlow, or Jax can be used to train the DL models.

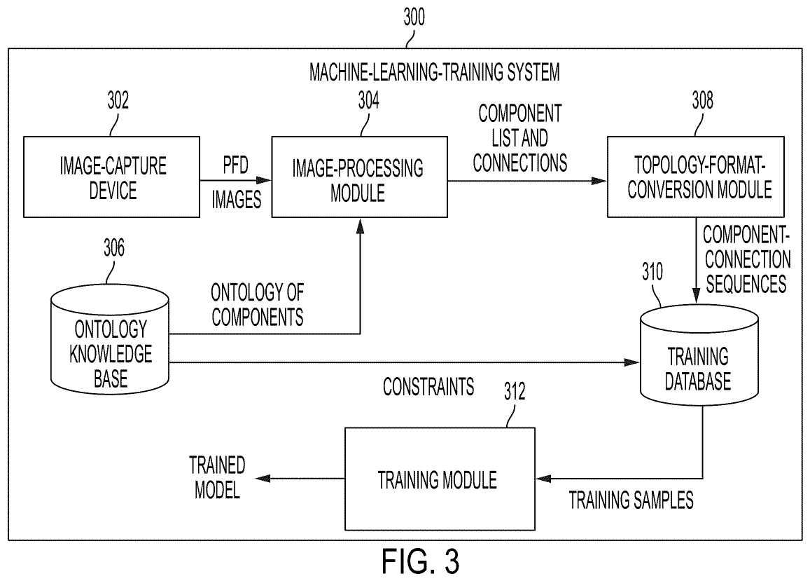

FIG. 3 presents a block diagram of an exemplary machine-learning-training system for training a machine-learning model for generating topologies of to-be-designed physical systems, according to one embodiment. Machine-learning-training system 300 can include an image-capture device 302, an image-processing module 304, an ontology knowledge base 306, a topology-format-conversion module 308, a training database 310, and a training module 312.

Image-capture device 302 can be a scanner or a camera that can obtain images of the system diagrams (e.g., PFDs) and send the images to image-processing module 304. Image-processing module 304 can use various image-processing techniques (which can include machine-learning based object-detection techniques) to extract topology information (including the components and their connections) from each PFD. For each PFD, the list of components and their connections can be sent to topology-format-conversion module 308, which converts the extracted topology information to a predetermined format, such that the topology of the system can be expressed using a formal language (e.g., statements (first-order logic- or propositional logic-based), graph neural networks, SMILES formulas, etc.). In some embodiments, topology-format-conversion module 308 can convert the topology of a system into a set of component-connection sequences.

Output of topology-format-conversion module 308 (e.g., the component-connection sequences) can be added to training database 310 as training samples. In addition, ontology constraints from ontology knowledge base 306 can also be added to training database 310 as negative training samples. The training samples stored in training database 310 can be used by training module 312 to train a machine-learning model (e.g., a generative model) such that, given a functional label of a to-be-designed physical system, the trained machine-learning model can provide/generate samples of the topology/architecture of a system that can provide the required functionality. Training module 312 can select different training platforms/methods for training the model, depending on the type of the model. In one embodiment, the to-be-trained model is a DL model, and training module 312 can use DL training platforms, such as Pytorch, TensorFlow, or Jax to train the model.

### System Design Generation

The trained generative models can produce system architecture samples that satisfy a set of qualitative requirements (e.g., the functionality of the system). For example, if the required function is high-pass filtering, the trained model can output sample topologies of high-pass filters. Such samples can be referred to as the “meta design” of the system. The next design step is to instantiate the “meta” design solution with explicit components and component parameters.

Assume that the automated design system can access a library of components, which also includes the behavioral description of the components. Such libraries can be part of simulation tools, such as Matlab/Simulink, or Modelica language-based tools, such as OpenModelica or Dymola. These libraries can include examples of physical components (e.g., pumps, pipes, valves) and their behavioral descriptions by means of mathematical models (e.g., ordinary differential equations (ODEs)). Often, these libraries can include templates of components, and different instantiations can be obtained by changing the component parameters. For example, a pipe can be characterized by a material that dictates heat exchange, and a diameter. Instantiations of different pipes can be obtained by varying the material and diameter parameter values. The component parameters can be chosen so that a given set of quantitative requirements (e.g., a minimum temperature at the radiator, the cutoff frequency of the filter, etc.) are satisfied. In some embodiments, an optimization-based parameter estimation process can be implemented. During operation, optimization algorithms (e.g., nonlinear least square) search the parameter space of the components (e.g., pipe diameter, pipe material, pump flow rate) until the quantitative requirements are satisfied. If the optimization algorithms fail to find suitable parameters, the meta design may be a failed design, and the generative model can output another sample topology that satisfies the qualitative requirements. Instantiation of the new meta design example can be performed. This process can repeat until a design solution satisfying both the qualitative and quantitative requirements is found.

In further embodiments, multiple design solutions can be generated, and these solutions can be further evaluated using other metrics, such as manufacturing cost, maintenance cost, etc.

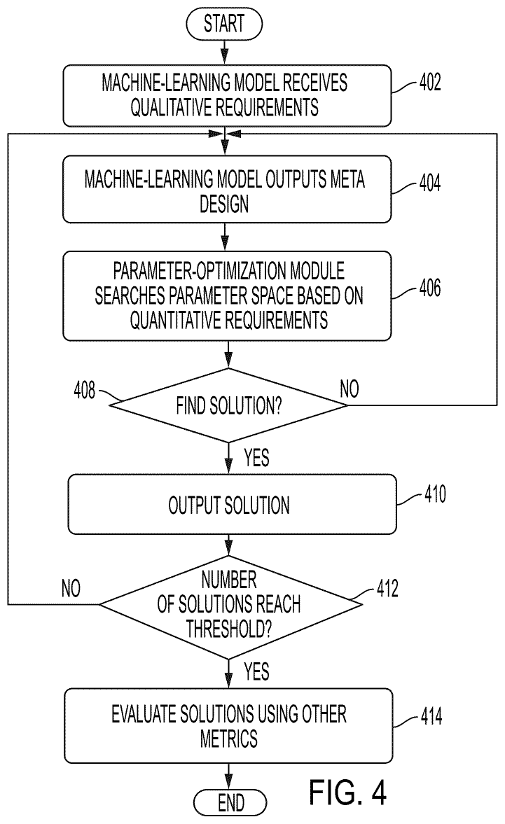

FIG. 4 presents a flowchart illustrating an exemplary process for generating a design solution of a physical system, according to one embodiment.

During operation, the trained machine-learning model receives a set of qualitative requirements of a to-be-designed physical system (operation 402). The set of qualitative requirements can include the functional description or purpose of the to-be-designed physical system. For example, the qualitative requirements may specify that the to-be-designed system is an HVAC system, a heating system, a cooling system, a high- or low-pass filter, or an amine-treating system. In some embodiments, the qualitative requirements can also include constraints, such as ontological constraints.

The trained machine-learning model can output a meta design solution based on the qualitative requirements (operation 404). For example, the trained machine-learning model is a generative model that, when given a function Y (i.e., the label or functionality of the system), can sample from the probability distribution P(X|Y) that can be determined from the joint probability distribution P(X, Y). In other words, given Y the function, the trained machine-learning model can output X the topology with a certain probability P(X|Y). In some embodiments, when outputting the system topology, the trained machine-learning model can use the constraints (e.g., the ontological constraints) to filter out unsuitable system topologies.

The meta design can include a list of components and their connections. In some embodiments, the meta design can be in the same predetermined format of the samples. For example, the meta design can be a set of component-connection sequences, and the trained machine-learning model can predict the components in each sequence one by one.

Subsequently, a parameter-optimization module can search the parameter space of each component to instantiate the meta design based on a set of quantitative requirements of the to-be-designed physical system (operation 406) and determine if the search can find a design solution that satisfies the quantitative requirements (operation 408). The quantitative requirements of a to-be-designed physical system can specify, in quantity, certain criteria to be met by the designed physical systems. For example, for a heating system, the quantitative requirements can include the temperature at the radiator, the maximum energy consumption, etc.; and for a filter, the quantitative requirements can be the upper/lower cutoff frequency, the insertion loss, etc. If the search finds a design solution, the automated design system outputs the design solution (operation 410) and determines if the number of found solutions reaches a predetermined threshold (operation 412). If the total number of solutions is less than the threshold, the process returns to operation 404, where the trained machine-learning model outputs a new meta design. Otherwise, the automated design system evaluates the solutions using other metrics, such as manufacturing cost, maintenance cost, etc., until an optimum solution is identified (operation 414).

If the parameter search cannot find a design solution that satisfies the quantitative requirements, the design process returns to operation 404, where the trained machine-learning model outputs a new meta design.

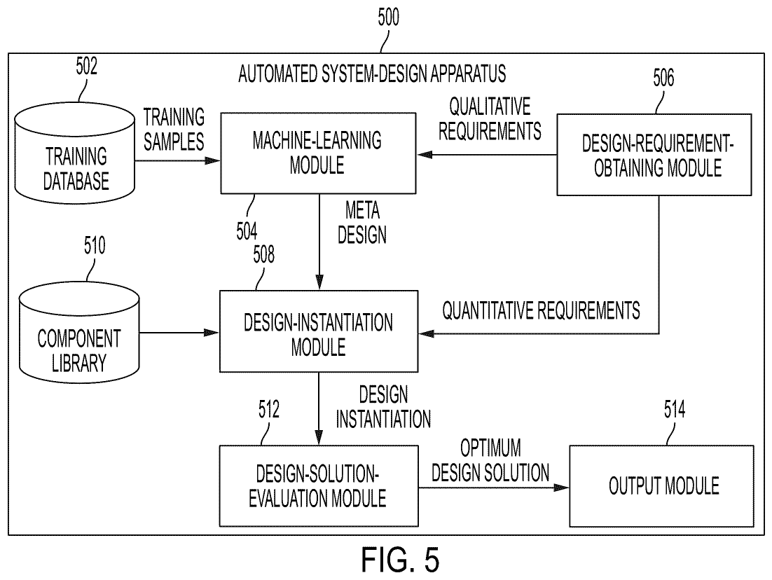

FIG. 5 illustrates a block diagram of an exemplary automated system-design apparatus for designing physical systems, according to one embodiment. Apparatus 500 includes a training database 502, a machine-learning module 504, a design-requirement-obtaining module 506, a design-instantiation module 508, a component library 510, a design-solution-evaluation module 512, and an output module 514.

Training database 502 stores a large number of training samples. In some embodiments, the training samples are examples of system architectures represented in a predetermined format, such as a formal language (in first-order logic or propositional logic) representation, a textural representation, a mixture of text and graphics, a graph neural network, SMILES formulas, etc. In one embodiment, each training sample can include a number of component-connection sequences, with each sequence indicating the connecting relationship among multiple components. In a further embodiment, a component-connection sequence can be plain text including the name of the components and their connection order (e.g., component A connects to component B connects to component C, etc.). Training database 502 may also include negative training samples, which may be generated based on the ontological constraints.

Machine-learning module 504 trains a machine-learning model using training samples from training database 502. Examples of the machine-learning model can include NLP machine-learning models, such as N-gram/RNN language models, hidden Markov models, probabilistic context-free grammar, naïve Bayes, latent Dirichlet allocation, Seq2Seq models, transformers, etc. In one embodiment, the machine-learning model is a DL generative model, and machine-learning module 504 can include a DL training platform (e.g., Pytorch, TensorFlow, Jax, etc.) to train the generative model. Moreover, machine-learning module 504 can execute the trained model using a set of qualitative requirements of a to-be-designed physical system. The qualitative requirements of the to-be-designed physical system can be received from design-requirement-obtaining module 506. In some embodiments, design-requirement-obtaining module 506 may also send a number of constraints to machine-learning module 504 to be used as input when executing the trained model. In alternative embodiments, training database 502 can also send constraints in the form of negative training samples to machine-learning module 504. Using the qualitative requirements and optionally the constraints as input of the trained machine-learning model, machine-learning module 504 can output one or more meta design solutions describing the topology of the to-be-designed physical system.

Design-instantiation module 508 can instantiate the meta design solution of the to-be-designed physical system by accessing component library 510, which can include a number of physical components and their behavioral descriptions. In one embodiment, design-instantiation module 508 can implement an optimization-based parameter estimation process, where optimization algorithms search the parameter space based on a set of quantitative requirements from design-requirement-obtaining module 506.

Design instantiations satisfying the quantitative requirements can be sent to design-solution-evaluation module 512, which evaluates the design solutions using other metrics, such as manufacturing cost, maintenance cost, etc. Design-solution-evaluation module 512 can identify and send an optimum design solution to output module 514, which outputs the optimum design solution to the user.

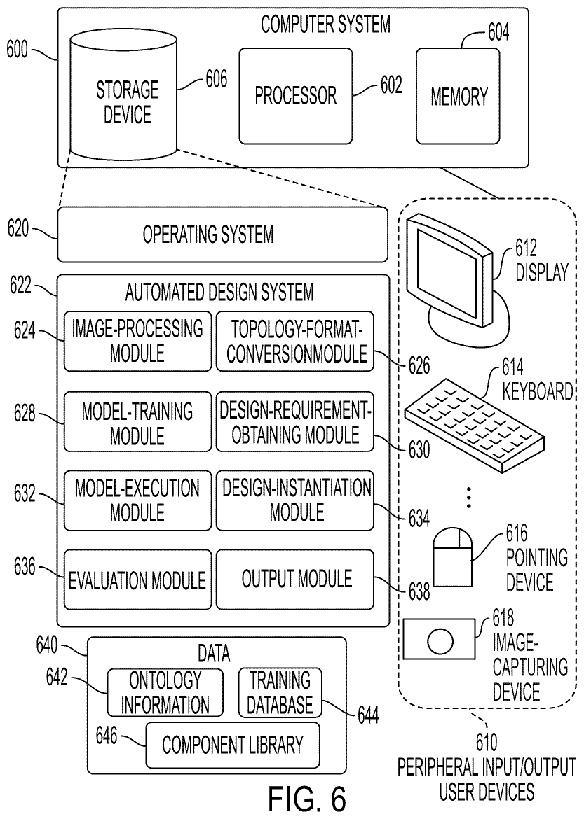

FIG. 6 illustrates an exemplary computer system that facilitates automated design of physical systems, according to one embodiment. Computer system 600 includes a processor 602, a memory 604, and a storage device 606. Furthermore, computer system 600 can be coupled to peripheral input/output (I/O) user devices 610, e.g., a display device 612, a keyboard 614, a pointing device 616, and an image-capturing device 618. Storage device 606 can store an operating system 620, an automated design system 622, and data 640.

Automated design system 622 can include instructions, which when executed by computer system 600, can cause computer system 600 or processor 602 to perform methods and/or processes described in this disclosure. Specifically, automated design system 622 can include instructions for processing images of diagrams of various systems to extract topology information of the systems (image-processing module 624), instructions for converting the extracted topology information into a predetermined format (topology-format-conversion module 626), instructions for training a machine-learning model (model-training module 628), instructions for obtaining design-requirements of a to-be-designed physical system (design-requirement-obtaining module 630), instructions for executing the machine-learning model to generate a meta design of the to-be-designed physical system based on the design requirements (model-execution module 632), instructions for instantiating the meta design solution (design-instantiation module 634), instructions for evaluating the design solutions (evaluation module 636), and instructions for outputting an optimum design solution (output module 638). Data 640 can include ontology information 642, a training database 644, and a component library 646.

In general, the disclosed embodiments provide a system and method for enabling automated design of physical systems. The automated design of a physical system can be based on a machine-learning model (e.g., a generative model). Training the machine-learning model can involve obtaining a large number of training samples. In some embodiments, topology information can be extracted from system diagrams (e.g., PFDs) and converted into a predetermined format that is amenable for training generative models. For example, the topology information can be represented using a formal language (e.g., propositional logic or first-order logic) as a number of component-connection sequences. The component-connection sequences can then be used to train an NLP machine-learning model. The trained model can use the design requirements (e.g., the qualitative requirements) of a to-be-designed physical system as input to generate, automatically, a topology for the to-be-designed physical system. The automated design process can also include the instantiation of the generated topology with components and their parameters by accessing a component library and searching the parameter space of each component.

The methods and processes described in the detailed description section can be embodied as code and/or data, which can be stored in a computer-readable storage medium as described above. When a computer system reads and executes the code and/or data stored on the computer-readable storage medium, the computer system performs the methods and processes embodied as data structures and code and stored within the computer-readable storage medium.

Furthermore, the methods and processes described above can be included in hardware modules or apparatus. The hardware modules or apparatus can include, but are not limited to, application-specific integrated circuit (ASIC) chips, field-programmable gate arrays (FPGAs), dedicated or shared processors that execute a particular software module or a piece of code at a particular time, and other programmable-logic devices now known or later developed. When the hardware modules or apparatus are activated, they perform the methods and processes included within them.

The foregoing descriptions of embodiments of the present invention have been presented for purposes of illustration and description only. They are not intended to be exhaustive or to limit the present invention to the forms disclosed. Accordingly, many modifications and variations will be apparent to practitioners skilled in the art. Additionally, the above disclosure is not intended to limit the present invention. The scope of the present invention is defined by the appended claims.

What is claimed is:

1. A computer-implemented method for automated design of a physical system, the method comprising:
obtaining qualitative and quantitative design requirements associated with the physical system;
inputting the qualitative design requirements to a trained machine-learning model to generate a topology of the physical system, wherein the topology specifies a number of components and connections among the components; and
determining parameters of the components based on the quantitative design requirements.

2. The method of claim 1, wherein the machine-learning model is a generative model.

3. The method of claim 2, further comprising training the generative model, which comprises:
obtaining images of a plurality of process flow diagrams (PFDs) associated with known systems;
extracting, from the images, topology information associated with the known systems; and
converting the topology information into a predetermined format.

4. The method of claim 3, wherein extracting the topology information comprises applying an image-processing technique to detect components and connections among the detected components within each image.

5. The method of claim 3, wherein training the generative model further comprises associating a label with the converted topology information from each PFD, wherein the label comprises a functional description of a system corresponding to the PFD.

6. The method of claim 3, wherein the predetermined format comprises a formal language representation of the topology information.

7. The method of claim 6, wherein the formal language representation comprises a number of component-connection sequences, wherein a respective component-connection sequence comprises a statement indicating a connection order of a number of components.

8. The method of claim 2, wherein the generative model comprises a natural language processing (NLP) machine-learning model comprising one or more of:
an N-gram language model;
a recurrent neural net (RNN) language model;
a hidden Markov model;
a model implementing probabilistic context-free grammars;
a naïve Bayes model;
a latent Dirichlet allocation (LDA) model;
a sequence to sequence (Seq2Seq) model; and
a transformer model.

9. The method of claim 1, wherein determining the parameters of the components comprises using an optimization technique to search a parameter space associated with a respective component.

10. The method of claim 9, further comprising:
in response to failing to find parameters of the components meeting the quantitative design requirements, generating, by the trained machine-learning model, an additional topology of the physical system.

11. A computer system for automated design of a physical system, the computer system comprising:
a processor; and
a storage device coupled to the processor and storing instructions, which when executed by the processor cause the processor to perform a method, the method comprising:
obtaining qualitative and quantitative design requirements associated with the physical system;
inputting the qualitative design requirements to a trained machine-learning model to generate a topology of the physical system, wherein the topology specifies a number of components and connections among the components; and
determining parameters of the components based on the quantitative design requirements.

12. The computer system of claim 11, wherein the machine-learning model is a generative model.

13. The computer system of claim 12, wherein the method further comprises training the generative model, which comprises:
obtaining images of a plurality of process flow diagrams (PFDs) associated with known systems;
extracting, from the images, topology information associated with the known systems; and
converting the topology information into a predetermined format.

14. The computer system of claim 13, wherein extracting the topology information comprises applying an image-processing technique to detect components and connections among the detected components within each image.

15. The computer system of claim 13, wherein training the generative model further comprises associating a label with the converted topology information from each PFD, wherein the label comprises a functional description of a system corresponding to the PFD.

16. The computer system of claim 13, wherein the predetermined format comprises a formal language representation of the topology information.

17. The computer system of claim 16, wherein the formal language representation comprises a number of component-connection sequences, wherein a respective component-connection sequence comprises a statement indicating a connection order of a number of components.

18. The computer system of claim 12, wherein the generative model comprises a natural language processing (NLP) machine-learning model comprising one or more of:
an N-gram language model;
a recurrent neural net (RNN) language model;
a hidden Markov model;
a model implementing probabilistic context-free grammars;
a naïve Bayes model;
a latent Dirichlet allocation (LDA) model;
a sequence to sequence (Seq2Seq) model; and
a transformer model.

19. The computer system of claim 11, wherein determining the parameters of the components comprises using an optimization technique to search a parameter space associated with a respective component.

20. The computer system of claim 19, wherein the method further comprises:
in response to failing to find parameters of the components meeting the quantitative design requirements, generating, by the trained machine-learning model, an additional topology of the physical system.
